(19) United States
(12) Patent Application Publication
(10) Pub. No.: US 2020/0272632 A1
(43) Pub. Date: Aug. 27, 2020

(54) SYSTEMS AND METHODS FOR SELECTING SPECIALITY CHEMICALS

(71) Applicant: Henkel Limited, Hertfordshire (GB)

(72) Inventor: Gerard McGurk, Somerset (GB)

(21) Appl. No.: 16/871,014

(22) Filed: May 10, 2020

Related U.S. Application Data
(63) Continuation of application No. PCT/EP2018/080956, filed on Nov. 12, 2018.

(30) Foreign Application Priority Data
Nov. 10, 2017 (GB) 1718627.1

(51) Int. Cl. G06F 16/2457; G06F 30/20; B33Y 50/00; B29C 64/386

(52) U.S. Cl. CPC G06F 16/24578; B29C 64/386; B33Y 50/00; G06F 30/20

(57) ABSTRACT

A computer-implemented method (400) of selecting a specialty chemical or a device for use with a specialty chemical includes: receiving (402) an input indicative of a plurality of physical properties that describe an application in which a specialty chemical is to be used; retrieving (404), from a data store (224), a plurality of scores, wherein each score indicates the suitability of a particular specialty chemical or a particular device to a particular one of the plurality of physical properties; calculating (406) an overall score for each of a plurality of specialty chemicals or each of a plurality of devices by combining the retrieved scores for each specialty chemical or each device; and selecting (408) one or more specialty chemicals or devices having an optimum overall score.

### TECHNICAL FIELD

The present disclosure generally relates to systems and methods for selecting a specialty chemical. The present disclosure also relates to systems and methods for selecting a device to be used with a specialty chemical.

### BACKGROUND

A specialty chemical is a chemical product that is selected on the basis of its performance or its function. Examples of specialty chemicals include adhesives, coatings and sealants. A vast range of specialty chemicals is available, with each specialty chemical having different properties that render it particularly suitable for some applications but less suitable for other applications. Thus, there exists a problem of selecting the specialty chemical that is most suited to a given application from the wide range of available specialty chemicals.

Currently, a user seeking assistance in selecting a specialty chemical for a given application may call a manufacturer's or distributor's helpline for advice from an expert or may use online tools that suggest chemicals based on user input. However, both of these approaches can lead to the selection of a specialty chemical that is not optimal for the application in question. For example, the advice provided by an expert may be subjective, while existing online tools are only capable of considering a very small subset of each chemical's properties when making a suggestion.

There is therefore a need for technology capable of providing an improved selection of a specialty chemical for a given application.

### SUMMARY

A user faced the task of selecting a speciality chemical will likely not have sufficient knowledge of the plethora of various selection options as well as perhaps the likely most suitable speciality chemical for a given application or specific set of conditions or physical parameters related to the application. The present disclosure provides systems and methods for selecting a specialty chemical or a device for use with a specialty chemical. The present disclosure provides an automated process for efficiently identifying a speciality chemical. Such an automated process provides an example advantage of increased speed of selection of providing the speciality chemical. Specifically, greater amounts of data, and different types of data, may be evaluated in a timely fashion. Another example advantage of the present disclosure is the minimization (and in some instances) elimination of human error and subjectivity or basis which may be provided by a so-called expert associated with a particular manufacturer.

A computer-implemented method of selecting a specialty chemical or a device for use with a specialty chemical may comprise: receiving an input indicative of a plurality of physical properties that describe an application in which a specialty chemical is to be used; retrieving, from a data store, a plurality of scores, wherein each score indicates the suitability of a particular specialty chemical or a particular device to a particular one of the plurality of physical properties; calculating an overall score for each of a plurality of specialty chemicals or each of a plurality of devices by combining the retrieved scores for each specialty chemical or each device; and selecting one or more specialty chemicals or devices having an optimum overall score.

The plurality of specialty chemicals may comprise a resin, an adhesive, a coating, a sealant, a cleaner, a lubricant and/or a release agent. The plurality of physical properties may include at least one property relating to the design of an assembly to be bonded by an adhesive. The at least one property relating to the design of the assembly may include: a material to which the adhesive will be applied; a surface area to be bonded by the adhesive; a gap between parts to be bonded by the adhesive; or an optical property of the adhesive. Alternatively or additionally, the plurality of physical properties may include at least one property relating to the design of an object to be formed by a resin. The object may be formed by the resin using additive manufacturing. The plurality of physical properties may include a setting time of an adhesive. The plurality of physical properties may include at least one mechanical requirement of an adhesive. The at least one mechanical requirement may include: a strength of a bond; an elasticity of a bond; or a toughness of a bond. The plurality of physical properties may include at least one environmental condition. The at least one environmental condition may include: an environmental temperature; or a chemical property of an environment.

The plurality of physical properties may include at least one property relating to the design of an object to be coated by a coating. Alternatively or additionally, the plurality of physical properties may include at least one property relating to the design of an object to be sealed by a sealant. Alternatively or additionally, the plurality of physical properties may include at least one property relating to the design of an object to be cleaned by a cleaner. Alternatively or additionally, the plurality of physical properties may include at least one property relating to the design of an object to which a release agent is to be applied.

The method may further comprise analysing the received input to identify a plurality of mutually incompatible physical properties of the application. The method may further comprise outputting a recommendation to modify the application in order to mitigate the mutually incompatible physical properties of the application.

Receiving an input indicative of a plurality of physical properties may comprise: receiving a computer aided design file; and processing the computer aided design file to identify one or more physical properties of the application in which a specialty chemical is to be used. The method may further comprise estimating a required quantity of a specialty chemical based on the computer aided design file. The plurality of devices comprises a device for dispensing a specialty chemical. The method may further comprise ranking the selected chemical(s) or device(s) in accordance with their respective overall scores. The plurality of physical properties may include at least one property of an additive manufacturing process.

Disclosed embodiments may provide an apparatus configured to perform the method described above. Disclosed embodiments may provide a computer-readable medium comprising instructions that, when executed by a computer, cause the computer to perform the method described above.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate disclosed embodiments and, together with the description, serve to explain the disclosed embodiments. In the drawings:

FIG. 1 depicts an example of a system environment for selecting a specialty chemical, consistent with embodiments of the present disclosure.

FIG. 2 depicts an example of a server, consistent with embodiments of the present disclosure.

FIGS. 3A, 3B and 3C are exemplary graphical displays of a specialty chemical selection interface, consistent with embodiments of the present disclosure.

FIG. 4 is a flow chart of an exemplary method of selecting a specialty chemical, consistent with embodiments of the present disclosure.

FIG. 5 is an exemplary set of scores, consistent with embodiments of the present disclosure.

### DETAILED DESCRIPTION

Reference will now be made in detail to the disclosed embodiments, examples of which are illustrated in the accompanying drawings. Wherever convenient, the same reference numbers will be used throughout the drawings to refer to the same or like parts.

The present disclosure generally relates to a computer system for selecting a specialty chemical and/or a device for use with a specialty chemical. The present disclosure provides an automated process for efficiently identifying a speciality chemical. Such an automated process provides an example advantage of increased speed of selection of providing the speciality chemical. Specifically, greater amounts of data, and different types of data, may be evaluated in a timely fashion. Another example advantage of the present disclosure is the minimization (and in some instances) elimination of human error and subjectivity or basis which may be provided by a so-called expert associated with a particular manufacturer.

In the following description, the term “product” is used to refer to a specialty chemical, or a device for use with a specialty chemical, that can be selected using the computer system. The computer system is configured to receive an input that defines some or all of the physical properties of an application of a specialty chemical. The term “application” refers to a particular use of a specialty chemical. An application of a specialty chemical can be described or defined by its physical properties. For example, an application of an adhesive may be to bond two parts together, and the physical properties describing that application may include the material of either or both parts, the surface area to be bonded, the gap between the parts, the desired setting time of the adhesive and/or a mechanical requirement of the bond, etc. The task of selecting a product that is most suitable for a particular application becomes more difficult as the number of available products increases, and as the number of physical properties to be taken into account increases.

The computer system disclosed herein uses a scoring algorithm to select one or more products that are most suitable for a particular application. As discussed in greater detail below, the scoring algorithm takes into account the suitability of multiple products to each of a plurality of physical properties that describe an application. The most suitable product is thus selected in an objective manner. The computer system can provide faster and more detailed assistance than is currently available, for example, by consulting an expert via a helpline. The computer system can also reconcile the many competing requirements of an application in order to select the most suitable product.

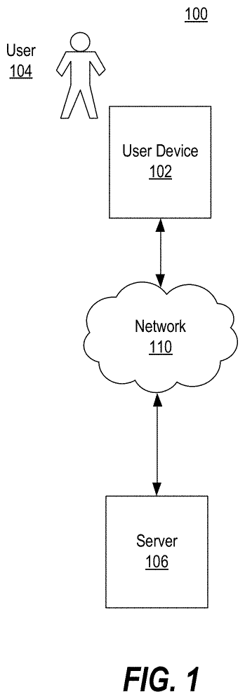

FIG. 1 is a schematic diagram of an exemplary system 100 for selecting a specialty chemical, or a device for use with a specialty chemical, in accordance with the present disclosure. As shown in FIG. 1, the system 100 may include a user device 102 a server 106. The components of system 100 may communicate through a network 110. The components and arrangements shown in FIG. 1 are not intended to limit the disclosed embodiments, however, as the components used to implement the disclosed processes and features may vary. Other components known to one of ordinary skill in the art may be included in the system 100 to perform tasks consistent with the disclosed embodiments. Moreover, the system 100 may be implemented using a single computing device, rather than using a client/server architecture such as that shown in FIG. 1. For example, the present disclosure may be implemented using only the user device 102, without the need for a server 106. In this example, the user device 102 may have similar functionality to that of the server 106, as described in more detail below.

The user device 102 may be any type of computing device that can be operated by a user 104. For example, the user device 102 may be a personal computer (such as a desktop, laptop or tablet computer), a mobile device with computing ability (such as a smartphone or a wearable device), or any combination of these computers and/or affiliated components. The user 104 may operate user device 102, and/or another computer (not shown), to interact with system 100.

The system 100 may have multiple types of users 104 such as, for example, engineers, process specialists or chemists, who may require a product for an industrial application. The user 104 may be a private individual requiring a product for a domestic application such as home repair, automobile repair, or a hobby. The user 104 may be a customer representative assisting a customer via telephone, web chat, and/or a face-to-face interaction. Other types of users 104 are possible.

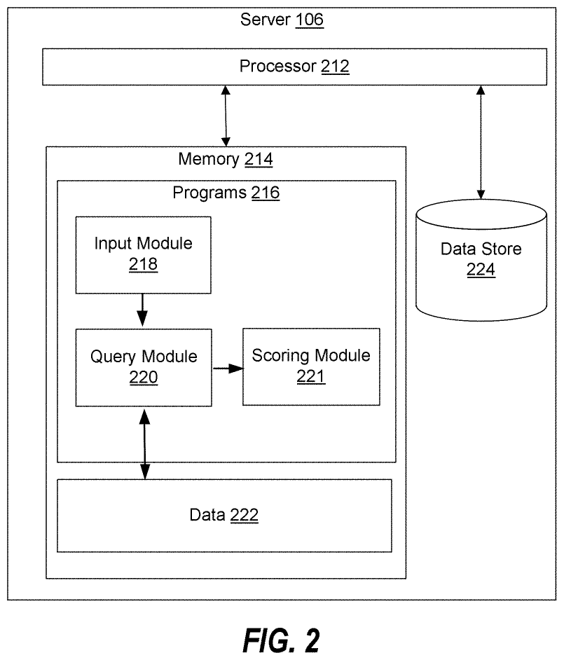

The server 106 may include one or more server computing devices or storage services. For example, the server 106 may be implemented with a cloud computing service, such as Microsoft Azure™ or Amazon Web Services™ In such examples, the server 106 may comprise a plurality of geographically distributed computing systems executing software for performing one or more functions of the disclosed methods. The server 106 is described in more detail below, with reference to FIG. 2.

The network 110 may comprise any type of computer networking arrangement used to exchange data. For example, the network 110 may be the Internet, a private data network, a virtual private network using a public network, and/or other suitable connection(s) that enables information to be sent and received between the components of the system 100. The network 110 may also include a public switched telephone network (PSTN) and/or a wireless cellular network. For example, user input may be received via telephone using an interactive voice response system.

As shown in FIG. 2, the server 106 may include one or more processor(s) 212, a memory 214 storing one or more program(s) 216 and data 222, and a data store 224. The server 106 may be a single server or may be configured as a distributed computer system including multiple servers or computers that interoperate to perform one or more of the processes and functionalities associated with the disclosed embodiments.

The processor(s) 212 may be one or more known processing devices, such as microprocessors manufactured by Intel™ or AMD™ or licensed by ARM. The processor 212 may constitute a single core or multiple core processors that execute parallel processes simultaneously. For example, the processor 212 may be a single core processor configured with virtual processing technologies. In certain embodiments, the processor 212 may use logical processors to simultaneously execute and control multiple processes. The processor 212 may implement virtual machine technologies, or other known technologies to provide the ability to execute, control, run, manipulate, store, etc. multiple software processes, applications, programs, etc. In another embodiment, the processor 212 may include a multiple-core processor arrangement (e.g., dual, quad core, etc.) configured to provide parallel processing functionalities to allow a user device 102 to execute multiple processes simultaneously. It will be appreciated that other types of processor arrangements could be implemented that provide for the capabilities disclosed herein.

In some embodiments, the server 106 may include one or more storage devices configured to store information used by the processor 212 (or other components) to perform certain functions related to the disclosed embodiments. In one example, the server 106 may include a memory 214 that includes instructions to enable the processor 212 to execute one or more applications, such as server applications, a product selection application, network communication processes, and any other type of application or software known to be available on computer systems. Alternatively or additionally, the instructions, application programs, etc. may be stored in the data store 224. The memory 214 and/or the data store 224 may include a volatile or non-volatile, magnetic, semiconductor, tape, optical, removable, non-removable, or other type of storage device or tangible (i.e., non-transitory) computer-readable medium.

In one embodiment, the server 106 includes a memory 214 that stores instructions that, when executed by the processor 212, cause the processor to perform one or more operations consistent with the functionalities disclosed herein. The processor 212 may execute one or more programs located remotely from system 100. For example, the server 106 may access one or more remote programs, that, when executed, perform functions consistent with the present disclosure.

The data store 224 is configured to store information, and may be accessed and/or managed by the server 106. By way of example only, the data store 224 may include a relational database, a non-relational database, a spreadsheet, a table, a flat file and/or an object. The data store 224 need not be implemented on the same computer as the server 106, as illustrated in FIG. 2. In particular, the server 106 may communicate with one or more remote data stores (not shown) through the network 110.

The data store 224 stores information about a plurality of products, e.g., specialty chemicals and/or devices for use therewith. For each product, the information stored in the data store includes a plurality of scores. Each score is a value (such as an integer, floating point or Boolean value) that indicates the suitability of a product to one or more physical properties of an application. The term “physical properties” may include any relevant properties of an application, including mechanical properties, chemical properties, and/or compatibility of a product. For example, mechanical properties can include flexibility, viscosity, elasticity, strength and/or toughness. Chemical properties can include, for example, composition, toxicity, and/or required curing agents. Compatibility generally refers to a product's compatibility with one or more chemicals and/or materials that may be present in an application. For example, the compatibility of an adhesive may describe that adhesive's ability to form a bond with a particular substrate. Other examples of physical properties can include setting time and/or temperature resistance. It will be appreciated that these are purely non-limiting examples of physical properties.

The data store 224 may store products by category and/or application. For example, a product that is a specialty chemical may be categorized as a resin, an adhesive, a coating, a sealant, a cleaner, a lubricant or a release agent. A product that is a device may be categorized as a dispensing device, a curing device, a robot, a valve, a reservoir or a three-dimensional (3D) printing device. Applications may include, for example, thread locking, thread sealing, flange sealing, cylindrical bonding and/or flat-face bonding. A thread locking application refers to the use of a specialty chemical to prevent loosening, leakage, or corrosion of fasteners such as screws and bolts. A thread sealing application refers to the use of a specialty chemical to fill space around fasteners, thereby preventing and/or stopping leakages. A flange sealing application refers to the use of a specialty chemical to fill a space between parts, thereby preventing and/or stopping leakages. A cylindrical bonding application refers to the use of a specialty chemical to increase the strength of a press fit or slip fit assembly. A flat-face bonding application refers to the use of a specialty chemical to bond two flat surfaces together. Other categories and applications are possible.

For example, for a certain product, the data store 224 may store one or more scores indicative of the product's thermal resistance, maximum working temperature, compatibility with one or more materials, curing time, etc. The scores may be numeric values or may be words or phrases such as “Good” or “Very Good” associated with numerical values. For example, a product with high elasticity may have an elasticity score of 1, while another product with a low elasticity may have an elasticity score of 0. The score for a property may be associated with the product having a measurement of the property within a given range. For example, a curing time score of 0 may indicate a product has a curing time between 0 and 30 minutes; a score of 0.1 may indicate a curing time between 30 minutes and one hour; a score of 0.2 may indicate a curing time between one hour and 1.5 hours; and so on. It should be noted that the numerical values of the scores and the interpretations of the scores may be arbitrary, and other scoring systems may be used. For example, different properties may be scored on different scales, e.g., 0 to 1, 1 to 0, 0 or 1, −1 to 1, “Poor” to “Very Good,” etc.

According to some example embodiments, the scores for each product may be determined by comparing performance test data available for that product against requirements described in the selection criteria provided by a user. The particular score attributed for each product is related to how well the product performance data fulfils the selection criteria. For example 1.0=meets all requirements, 0.1=performance close to requirements; 0.01=may meet requirements in some circumstances, 0=fails to meet the requirements).

Scoring may be carried out by a suitably qualified engineer by comparing the test data with the selection criteria. However, if the performance data was available in a consistent database format then it is of course possible that scoring could be performed automatically using a suitable algorithm.

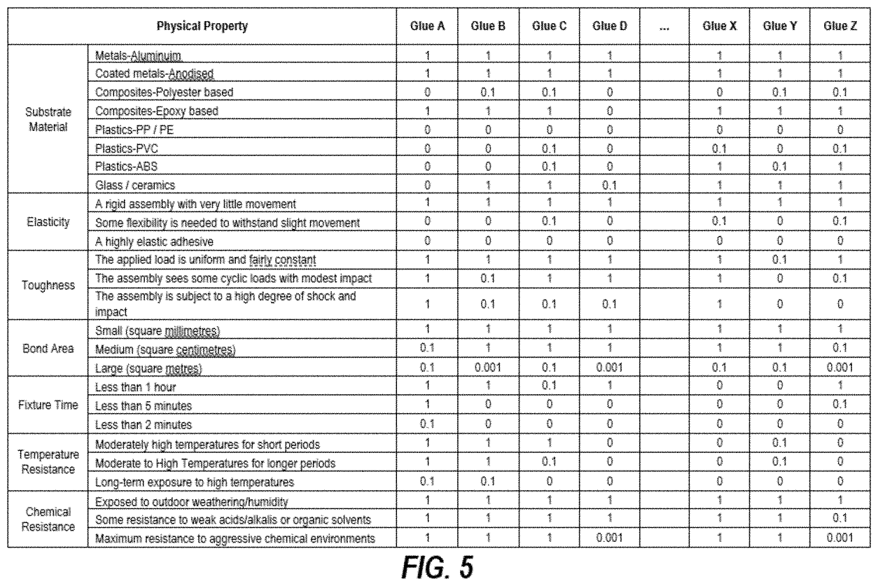

To illustrate the principles of the scores, FIG. 5 is an exemplary set of scores indicating the suitability of various specialty chemicals to different physical properties of an application. More particularly, FIG. 5 shows scores indicative of the suitability of various adhesives (labelled “Adhesive A” to “Adhesive Z”) to various physical properties. The physical properties include the substrate material, elasticity, toughness, bond area, fixture time, temperature resistance and chemical resistance. Each physical property has one or more options. For example, the substrate material property has eight possible options, each corresponding to a different material. As another example, the fixture time property has three options, each of which corresponds to a different range of times. For each adhesive, a score is stored for each option of each physical property. The scores have values ranging from 0 to 1, where a score of 1 indicates that the adhesive is particularly well suited to that option of that physical property. It will be appreciated that FIG. 5 is purely an example of how scores can indicate the suitability of products to the physical properties of an application. Whilst FIG. 5 shows scores in the form of a table, it will be appreciated that scores need not be stored in a tabular form.

Referring again to FIG. 2, the one or more program(s) 216 stored in the memory 214 and executed by processor(s) 212 may include an input module 218, a query module 220, and/or a scoring module 221. The programs 216 may be configured to: receive an input indicative of the physical properties of an application in which a specialty chemical is to be used; analyse the received data using one or more rule sets, computer models, or other processing logic; generate data associated with one or more graphical user interfaces; generate an overall score that indicates whether or not a product is suitable for the application, generate a ranked list of products according to the overall scores for each product; generate one or more communications and/or commands to other computer systems or devices such as user device 102; and/or update the graphical user interface(s) to display to the user 104 the ranked list of products.

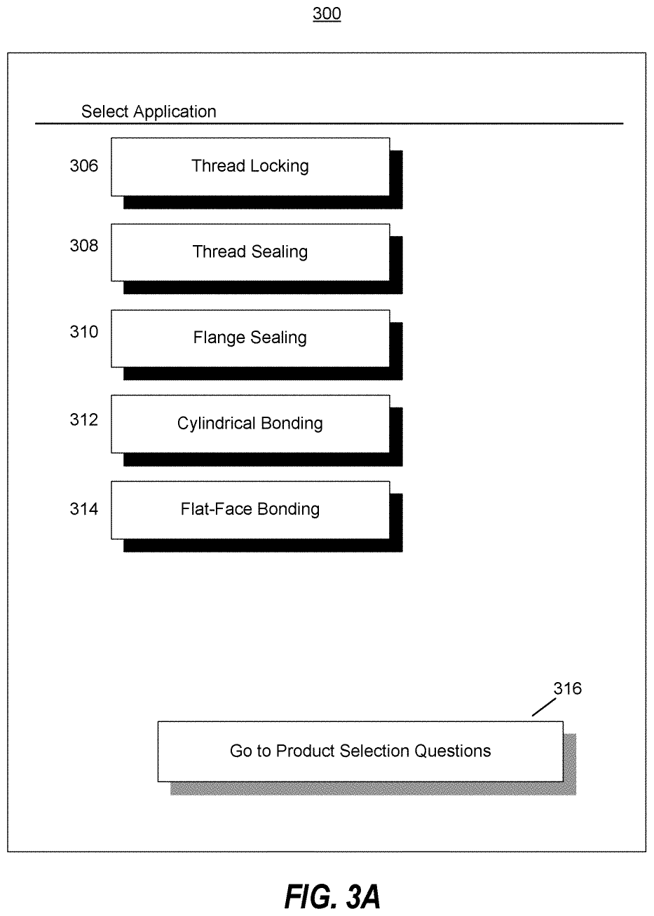

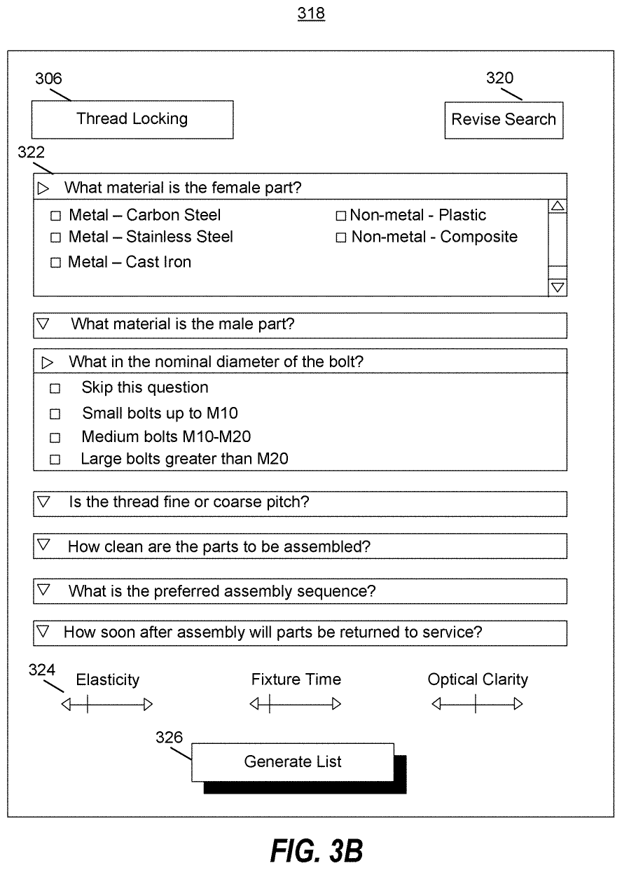

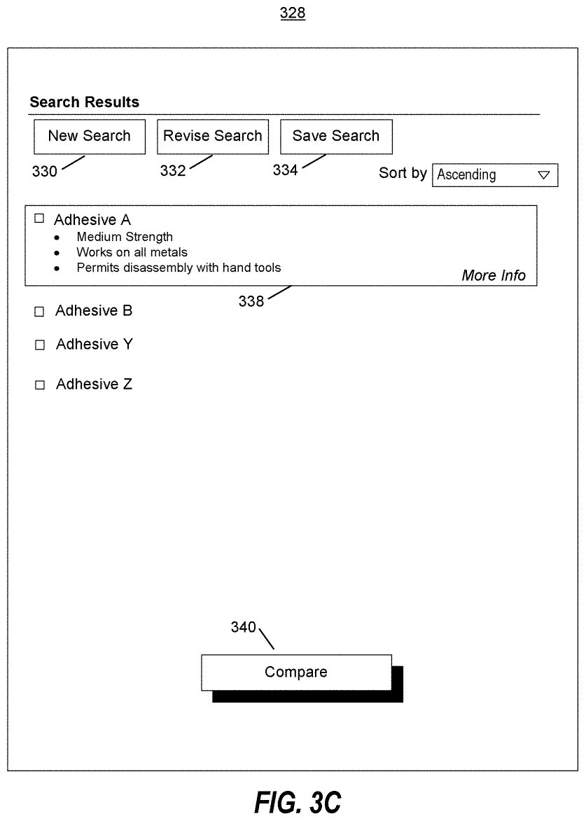

The input module 218 may receive an input from a user 104 via a graphical user interface. The input may indicate one or more physical properties that describe an application in which a specialty chemical is to be used. For example, via a user interface, the user 104 may complete a questionnaire and/or web form prompting the user to enter desired characteristics of a specialty chemical and/or design specifications of the application. FIGS. 3A and 3B show examples of such user interfaces. Alternatively or in addition, the user may input free-form text.

The physical properties received by the input module 218 may indicate a type of application and/or a category of product. For example, the user 104 may select a type of application, such as thread locking, thread sealing, flat-face bonding, or cylindrical bonding. Alternatively or in addition, the user may select a category of product, such as an adhesive, a coating, a resin, or a lubricant, etc. The user 104 may be prompted to select one or more properties from a listing of properties and/or materials.

In some embodiments, the user may upload a design file (e.g., a computer-aided design (CAD) file) to the server 106. The input module 218 may analyse information in the CAD file to identify one or more physical properties of an application of a specialty chemical. For example, the CAD file may contain a design for an object. The CAD file may include information such as the dimensions, material and/or surface area of the object. The input module 218 is configured to analyse the information contained in the CAD file, and to automatically identify one or more physical properties of an application involving the object. As another example, the CAD file may contain design information for two parts that the user wishes to bond together in a certain orientation. Upon analysis of the CAD file, the input module 218 may automatically identify certain properties, such as bond strength and/or flexibility, required to bond the two parts. If necessary, the user may be prompted to input additional information that is not contained in a CAD file. Thus, it should be appreciated the input module 218 may be able to identify physical properties which may be unknown to the user based on an analysis of the received input.

The query module 220 is configured to receive information from the input module 318 indicative of the user's desired product application and properties. The query module 220 is configured to query the data store 224, to retrieve a list of products matching the user's indicated application or product category. The query module 220 may retrieve a list of identified products and one or more scores associated with the properties of each product. As previously described, each score may indicate the suitability of a particular product to a respective physical property of an application.

For example, if the user indicates, via the graphical user interface, that he needs an adhesive that has a long working time and is compatible with a plastic, the query module 320 may query the data store 224 and retrieve a list of adhesive products and their associated working time and compatibility scores.

It should be appreciated the data 224 provides an adaptable and current listing of products. Thus, the query module 220 provides an example advantage of being able to filter through a vast amount of different potential products in a timely manner, without human error, and without subjectivity or basis from an expert associated with a particular manufacturer.

Furthermore, the query module 220 aids in eliminating human error by retrieving the list of products according to an identified application and/or property. For example, as illustrated in FIG. 5, the data store 224 may comprise information on each product (e.g., Adhesive A, Adhesive B . . . Adhesive Z) with respect to the product's physical properties in relation to different applications or conditions. The different combinations of products, physical properties and applications are scored with respect to effectiveness.

Therefore, aspects of the present disclosure comprise the calculation and maintenance of such scores. Additional aspects of the present disclosure comprise an arrangement of such information within the data store to ensure efficient and timely query and retrieval of relevant information.

The scoring module 221 is configured to generate an overall score for each product, based on retrieved list of products and their associated scores. The overall score represents the overall suitability of a particular product to the application, based upon that product's scores for each of the physical properties that define the application. The overall score is calculated by combining (by multiplying or adding, for example) the scores for each of the physical properties.

For example, the overall score for an adhesive product may be calculated in accordance with Equation 1:

f_{Overall}=f_{Area}×f_{Gap}×f_{Temperature}×f_{Toughness}×f_{Flexibility}×f_{Substrate1} (1)

In Equation 1, the respective scores for bond area, gap between bonded surfaces, working temperature, toughness, flexibility, and a first substrate material are multiplied to calculate the overall score. It will be appreciated that Equation 1 is just one example of how an overall score can be calculated, and that an overall score may be based upon other physical properties. It should be appreciated the scoring module may comprise or have access to any number of equations which may be predetermined for use with a particular application, product or physical property.

The scores for each property may be normalized before being combined. For example, each score may be normalized such that its value is between 0 and 1, or between −1 and +1. This can ensure that the scores associated with each physical property contribute towards the overall score, thereby avoiding any one physical property dominating the overall score. This allows the suitability of a product to be objectively determined. The scores can be normalized when they are stored in the data store 224, or the scores can be normalized when they are retrieved from the data store 224.

Alternatively or in addition, the scores may be weighted before being combined. This can allow the physical properties that are of greatest importance to the application having the greatest contribution to the overall score. The user may indicate, via the graphical user interface, each property's importance and each property score will be assigned a weight corresponding to the indicated level of importance. For example, a user may indicate that the working temperature of a product is an important factor, and therefore scoring module 221 may assign working temperature a higher weight when calculating the overall score. Weighting can be achieved by multiplying a score by a number between 0 and 1.

Once overall scores have been generated for each product in the list generated by query module 220, the scoring module 221 selects one or more products having an optimal overall score. The product(s) with the optimal overall score are those that are most suitable for the application. The optimal overall score will generally be the highest overall score, assuming that high scores are assigned to products that are well suited to a particular physical property. However, it is possible that low scores can be assigned to products that well suited to a particular physical property, in which case the optimal overall score will be the lowest overall score. The term “optimal overall score” should be construed accordingly.

The scoring module 211 may rank the selected products in accordance with their respective overall scores. The ranked list of products may be displayed to the user via a graphical user interface. The overall score for each product indicates how closely the properties of the product match the physical properties of the application in question. For example, a product with an overall score of 1 may be listed first and be indicated as a “Best Match” for the application specified by the user. Products having an overall score of 0 may be listed as “Not Recommended”, indicating that the properties of that product do not match those specified by the user. Alternatively, products that having an overall score of 0 may be excluded from the list.

Thereafter, an additional aspect of the present disclosure is analysing data within the data store by performing a calculation to determine an overall suitability of the product for the intended application. FIG. 3A is an exemplary first graphical user interface screen 300 of a product selection tool. The selection tool may generate a list of suggested products, such as specialty chemicals and/or devices for use with specialty chemicals, based on user input using one or more scoring algorithms. In some embodiments the system 100 may use initial input to determine which product scoring algorithm to apply to the user's input.

The user 104 may use the graphical user interface 300 to select a particular application, for example, thread locking 306, thread sealing 308, flange sealing 310, cylindrical bonding 312, or flat-face bonding 314, by clicking on the respective button displayed by the interface. Alternatively, the user 104 may select the application using a drop-down menu or by entering free-form text. Other applications may be selectable by the user.

After selecting an application, the user 104 may click the button 316 to proceed to more specific product property questions. In some embodiments, the button 316 may not activate until the user 104 has selected an application.

FIG. 3B is an exemplary second graphical user interface screen 318 configured to receive user input indicating the physical properties of an application. For example, the graphical user interface 318 may contain one or more drop-down menus 322, buttons, sliders 324, and/or text boxes configured to receive user input. The graphical user interface 318 may display the application that was previously selected via the user interface 300, for example, thread locking 306. In some embodiments, a revise search button 320 may allow the user to navigate to the previous screen 300 and modify their selection.

Based on the previous user input, the graphical user interface 318 may display one or more prompts. The displayed prompts may include questions and/or other methods through which the user 104 can provide more specific detail of the physical properties of an application. For example, the user 104 may be prompted to select a female part material and/or a male part material from a selectable list.

The exemplary questions presented in FIG. 3B are not meant to be an exclusory list. In some embodiments other applications, questions, and/or answers may be provided via the user interface. In some embodiments, “Skip Question” may be provided as an optional user input. In some embodiments, the user may input free-form text responsive to the one or more questions.

In addition to question-and-answer type input, the graphical user interface may receive input via a slider 324. For example, the slider for elasticity may be positioned by the user such that moving the slider to the left indicates the user desires low elasticity and moving the slider to the right indicates the user desires high elasticity. In other embodiments, the slider may be slid within a displayed elasticity range such that a user may slide the slider to the position of the desired elasticity. In some embodiments, the user may make a selection; for example, click a check box, indicating the property is either unimportant or not applicable.

The input that results from the user 104 specifying the physical properties of the application may be translated into scores, for example, by the input module 218. In one example, the user 104 may specify a desired fixture time of more than five minutes. Based on this input, the desired fixture time may be associated with fixture time scores corresponding to all fixture times greater than five minutes. The system may generate an overall score for the desired product using the scoring algorithm previously described with reference to FIG. 2.

In some embodiments, the user may upload a design file, via the user interface 318, from which the physical properties of an application can be automatically identified. In some embodiments, the system 100 may estimate the required quantity of a specialty chemical based on the design file provided by the user. For example, the system 100 may identify two surfaces that are to be bonded together by an adhesive, based upon metadata contained in the design file. The system 100 may then extract the dimensions of the surfaces from the identified surfaces from the design file, and calculate the surface area of each surface. The system 100 may finally calculate the volume of adhesive that is required to cover either or both surfaces.

After the user has input the physical properties of the application, the user may click the button 326 to generate a list of products that are suitable for the application.

FIG. 3C is an exemplary third graphical user interface screen 328 for displaying a list of suitable products to the user. The graphical user interface 328 may display buttons to begin a new search 330, revise the current search 332, and/or save the search 336 for future use. In some embodiments, the user may choose to sort the products, for example, in ascending or descending order of their overall scores. In some embodiments, a user may hover over a product with a cursor to display high level product information 338. In some embodiments, the user may click on a product name to be directed to the web page for that product.

In some embodiments, the user may select one or more products to compare. By clicking the compare button 340, the interface may display a table containing the properties of the selected products side-by-side

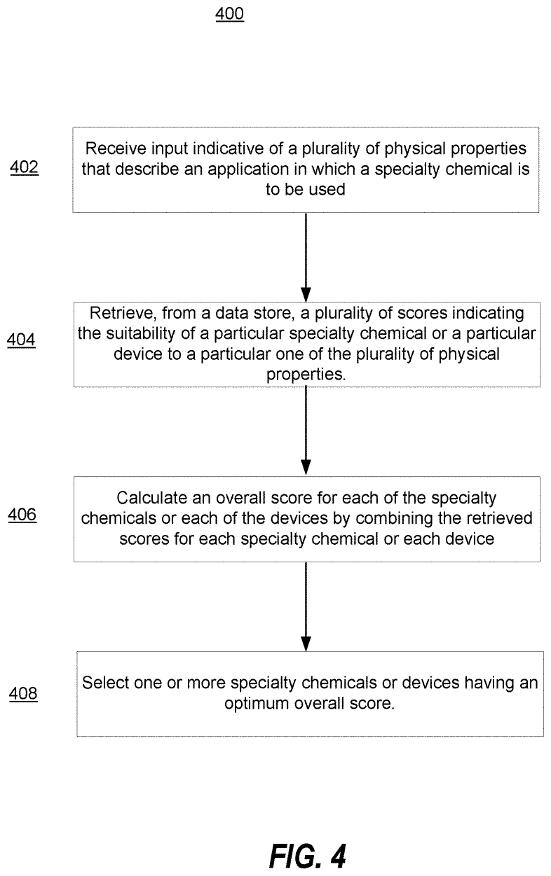

FIG. 4 is a flow chart of an exemplary method 400 of selecting a specialty chemical, or a device for use with a specialty chemical, in accordance with the present disclosure. At step 402, the server 106 (or another suitable computer system) receives an input that is indicative of a plurality of physical properties that describe an application in which a specialty chemical is to be used. The input may be received from a user 104 via a graphical user interface, such as graphical user interfaces 300 and/or 318. As part of step 402, the query module analyses the provided input. Such analysis involves identifying the user's desired product application and properties. In obtaining input from a user, the user may be presented with a number of options to choose from or questions related to various applications. The user may also submit drawings of the desired application. Therefore, it should be appreciated by analyzing the user provided input, the query module may derive information related to the application or properties of the product of which the user may be unaware.

At step 404, the server 106 retrieves, from the data store 224, a plurality of scores indicating the suitability of a particular specialty chemical or a particular device to a particular one of the plurality of physical properties. It should be appreciated aspects of the present disclosure comprise providing the information and arrangement of such information within the data store. Specifically, aspects of the present disclosure comprise the calculation and maintenance of such scores in order to provide extensive and current information with respect to different combinations of products, physical properties and applications are scored with respect to effectiveness.

At step 406, the server 106 calculates an overall score for each of the specialty chemicals or each of the devices by combining the retrieved scores for each specialty chemical or each device. A weight may optionally be assigned to each retrieved score based on a user input. As part of step 406 the scoring module may utilize a predetermined equation which may be specifically provided for different applications.

At step 408, the server 106 selects one or more specialty chemicals or devices having an optimum overall score. The specialty chemical(s) or device(s) with the optimal overall score are those that are best suited to the application. The server 106 may optionally display the selected products via a user interface 328. The server 106 may optionally rank the products in order from those that are most suited to the application to those that are least suited to the application.

The previously described system may be particularly useful for selecting specialty chemicals and/or devices for use in additive manufacturing (also known as 3D printing) applications. For example, a user may upload a CAD file containing information describing the design of one or more 3D printed parts. The system can analyse the CAD file to identify the most suitable specialty chemicals and/or devices to construct the 3D printed parts. For example, the system can select an adhesive to bond two or more 3D printed parts in the manner discussed above. The system may optionally advise to the user 104 on how to apply the adhesive to the parts to achieve the best result. As another example, the system can select a resin that can be used to form the 3D printed part. As yet another example, the system can select a suitable nozzle for use by a 3D printer to dispense a resin, an adhesive or another specialty chemical. Continuing this example, the system may select a suitable nozzle based on a flow rate, volume of chemical to be dispensed, viscosity, cure time, and/or working temperature indicated by the user.

In some embodiments, mutually incompatible physical properties of an application can be identified. If mutually incompatible physical properties are identified, the system can provide a recommendation to modify the application in order to avoid or mitigate the incompatibility. For example, a user may input a substrate material and a working temperature. The system may identify that the working temperature is greater than the melting point of a substrate. The system may then recommend that the user modifies the application by using a different substrate material. The system may further recommend one or more substrate materials that are compatible with the working temperature. It will be appreciated that other types of incompatibility may be identified and other types of recommendation may be provided.

While illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application, which examples are to be construed as non-exclusive. Further, the steps of the disclosed methods can be modified in any manner, including by reordering steps or inserting or deleting steps. It is intended, therefore, that the specification and examples be considered as example only, with a true scope being indicated by the following claims and their full scope of equivalents.

What is claimed is:

1. A computer-implemented method of selecting a specialty chemical or a device for use with a specialty chemical, the method comprising:
receiving an input indicative of a plurality of physical properties that describe an application in which a specialty chemical is to be used;
retrieving, from a data store, a plurality of scores, wherein each score indicates the suitability of a particular specialty chemical or a particular device to a particular one of the plurality of physical properties;
calculating an overall score for each of a plurality of specialty chemicals or each of a plurality of devices by combining the retrieved scores for each specialty chemical or each device; and
selecting one or more specialty chemicals or devices having an optimum overall score.

2. The method of claim 1, wherein the plurality of specialty chemicals comprises a resin, an adhesive, a coating, a sealant, a cleaner, a lubricant and/or a release agent.

3. The method of claim 1, wherein the plurality of physical properties includes at least one property relating to the design of an assembly to be bonded by an adhesive.

4. The method of claim 3, wherein the at least one property relating to the design of the assembly includes: a material to which the adhesive will be applied; a surface area to be bonded by the adhesive; a gap between parts to be bonded by the adhesive; or an optical property of the adhesive.

5. The method of claim 1, wherein the plurality of physical properties includes at least one property relating to the design of an object to be formed by a resin.

6. The method of claim 5, wherein the object is formed by the resin using additive manufacturing.

7. The method of claim 1, wherein the plurality of physical properties includes a setting time of an adhesive.

8. The method of claim 1, wherein the plurality of physical properties includes at least one mechanical requirement of an adhesive.

9. The method of claim 8, wherein the at least one mechanical requirement includes: a strength of a bond; an elasticity of a bond; or a toughness of a bond.

10. The method of claim 1, wherein the plurality of physical properties includes at least one environmental condition.

11. The method of claim 10, wherein the at least one environmental condition includes: an environmental temperature; or a chemical property of an environment.

12. The method of claim 1, further comprising:
analysing the received input to identify a plurality of mutually incompatible physical properties of the application.

13. The method of claim 12, further comprising:
outputting a recommendation to modify the application in order to mitigate the mutually incompatible physical properties of the application.

14. The method of claim 1, wherein receiving an input indicative of a plurality of physical properties comprises:
receiving a computer aided design file; and
processing the computer aided design file to identify one or more physical properties of the application in which a specialty chemical is to be used.

15. The method of claim 14, further comprising estimating a required quantity of a specialty chemical based on the computer aided design file.

16. The method of claim 1, wherein plurality of devices comprises a device for dispensing a specialty chemical.

17. The method of claim 1, further comprising ranking the selected specialty chemical(s) or device(s) in accordance with their respective overall scores.

18. The method of claim 1, wherein the plurality of physical properties includes at least one property of a specialty chemical useful in an additive manufacturing process.

19. An apparatus configured to perform the method of claim 1.

20. A computer-readable medium comprising instructions that, when executed by a computer, cause the computer to perform the method of claim 1.
